(19) United States
(12) Patent Application Publication
(10) Pub. No.: US 2021/0005571 A1
(43) Pub. Date: Jan. 7, 2021

(54) Bonding Device

(71) Applicant: F&S Bondtec Semiconductor GmbH, Braunau (AT)

(72) Inventors: Siegfried Seidl, Braunau/lnn Osterreich (AT); Johann Enthammer, Mining (AT)

(21) Appl. No.: 16/919,570

(22) Filed: Jul. 2, 2020

(30) Foreign Application Priority Data
Jul. 5, 2019 (DE) 10 2019 118 249.2

(51) Int. Cl. H01L 23/00

(52) U.S. Cl. CPC H01L 24/78; H01L 24/45; H01L 2224/78343; H01L 24/79; H01L 24/75

(57) ABSTRACT

Bonding device for producing bonding connections, in particular wire bonding connections, tape bonding connections and ball bonding connections, on carriers fixed outside the bonding device and having contact surfaces for the bonding connections, in different spatial directions with respect to the respective carrier, the bonding device comprising a base body, a bonding tool which is movable relative to the base body for applying a bonding force to a bonding means placed on the contact surface of the carrier to produce a material bond between the bonding means and the contact surface as a bonding connection, and bonding force generating means for generating a bonding force directed towards the contact surface when the bonding tool is placed on the carrier, wherein the bonding force generating means comprise a bonding force setting device for realizing a predetermined effective bonding force independently of its spatial direction of action.

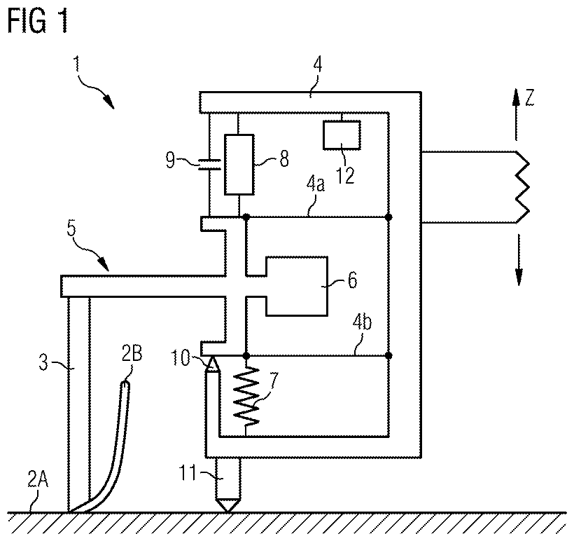

The invention relates to a bonding device for producing bond connections, in particular wire bond connections, tape bond connections and ball bond connections.

Bond connections of various types are used en masse in an immense number of electronic devices of all kinds and also for the realization of electronic components in many other industrial sectors, such as mechanical engineering, the automotive industry and the household appliance industry.

One of the most developed and widespread bonding processes is ultrasonic wire bonding (“Wedge Bonding”), which is basically a micro friction welding technique. As described, for example, in the Applicant's U.S. Pat. No. 4,619,397, an aluminium wire is subjected to rapid vibration by an ultrasonic transducer in contact with a substrate surface to which it is to be bonded, and at the same time pressed onto the surface. Under the action of the compressive force (bonding force) and the oscillation energy (bonding energy), an oxide layer on the surface is broken up and a materially bonded boundary layer connection is produced by strong deformation and local heating.

Another widely used bonding method is ball bonding, in which a ball-like thickening is created at one end of a bonding wire by melting it and pressing it onto a substrate surface in order to form a bond with the surface. A further bonding process worth mentioning is the so-called TAB (Tape-Automated Bonding), in which a foil with metallized conductor lines is efficiently connected to a large number of closely spaced bonding surfaces, such as bond pads on a semiconductor chip. Here, too, a bonding tool is used to create a bond between the conductors and the substrate under the action of a compressive force and ultrasonic oscillation energy—but without using a single bonding wire.

The above processes are usually carried out by means of relatively bulky and heavy bonding machines (wire or ball bonders, etc.), into which both the substrates and the bonding wire or tape are fed and in which the bonding process is carried out under the action of a vertically oriented compressive force on a component lying below the bonding wire or tape. Corresponding bonders are used en masse in industrial applications and have proven themselves for numerous applications.

Recently, however, there has been a demand for bonding solutions which can no longer be easily realized with such stationary bonders with a continuous vertical bonding tool under which the part to be bonded is placed.

The invention is therefore based on the task of providing a new type of bonding device with which this need can be met and which, in particular, permits the realization of bonding solutions on carriers which are spatially more complex in shape and/or cannot be placed in a stationary bonder due to their size.

This task is solved by a bonding device with the features of claim 1. Appropriate further development of the inventive idea are subject of the dependent claims.

The invention includes the idea of producing a bond connection not on a carrier located inside the bonding device but outside of it, depart from the previous consistent practice. It also includes the idea of designing the bonding device for making bonding connections in different spatial directions. Finally, the invention includes the idea that the bonding force generating means have a bonding force setting device for realizing a predetermined effective amount of bonding force independently of the spatial direction of action of the bonding tool. The last two aspects also represent a departure from the functional principles of the known and used bonding machines.

The bonding device, which is in accordance with the invention, opens up extensive new application possibilities for bonding technology in each of the above mentioned versions. In particular, groups or sequences of bond connections on components with complex spatial geometry can be produced without time-consuming and costly multiple clamping or transfer operations of the workpiece. This also includes “around the corner bonding” at bonding points that are located on surfaces of the component or substrate that are perpendicular or inclined to each other. It is thus also possible to create a plurality of bonding points on one or more components in a continuous operation, the bonding points of which lie on a space curve.

Combined with appropriate holding or guiding means (see below), even components or areas of components that are relatively far apart can be provided with bond connections in such a coherent process. This can include the use of unusually long bonding wires, for example, to create bonding connections in different areas of a larger machine or on a vehicle body (e.g. in the area of a dashboard or headliner). The bonding wire can also be routed over or around obstacles.

In addition to the aluminium wire bonding connections mentioned above as an example, the proposed bonding device can also be used to bond wires of other metals and especially insulated wires, which is particularly useful for some of the new applications outlined above.

In a design that is important from a current point of view, the bonding device is designed as a hand-held or robot-guided device with a handle or coupling piece for connection to a robot arm on the base body. On the one hand, in the view of the inventors, hand-guided bonding devices, also known as hand bonders, have numerous potential areas of application in areas such as building and air conditioning technology and the repair of electronic and electrical devices. On the other hand, robot-guided mobile bonding devices potentially have a broad industrial field of application, for example in machine and vehicle construction and especially in the automotive industry.

In a constructive design which is particularly important from the present point of view, the proposed bonding device is designed as a wire bonding device, with bonding wire feeding means for feeding a bonding wire as bonding agent onto the contact surface of the respective carrier and an ultrasonic transducer mechanically connected to the bonding tool for generating ultrasonic vibrations acting on the bonding tool.

Another important design feature is the ball bonding device, with bond wire feeding means for feeding a bond wire as a bonding agent to the contact surface of the respective carrier and a wire melting device for melting a free end of the bond wire to produce a bond ball.

Finally, a design as a TAB bonding device also appears to be promising, which comprises bonding foil feeding means for feeding a bonding foil as a bonding agent onto the contact surface of the respective carrier and an ultrasonic transducer mechanically connected to the bonding tool for generating ultrasonic vibrations acting on the bonding tool.

With an advantageous design of each of the above-mentioned versions, the bond force setting device has a position sensor for determining the spatial position of the direction of action of the bond tool and a calculation unit connected on its input side to the position sensor for calculating the bond force to be applied by the bond force generating means as a function of position. This special design feature compared to known bonding machines is due to the fact that the bonding force of these machines inevitably includes a well-defined and always the same gravity component due to the vertical orientation, whereas the gravity component flows in with different amounts depending on the direction if the direction of action of the bonding tool is not vertical (with “overhead bonding” also with negative values). Such a directional detection can be realized in a simple and cost-effective way with commercial spatial position sensors, which are used en masse, for example in smartphones.

In a further useful configuration of the bonding device according to the invention, the bonding force adjustment device comprises a bond wire deformation sensor for determining a deformation of the bond wire when the set bonding force is applied and a bonding force adjustment unit connected on the input side to the bond wire deformation sensor for deformation-dependent adjustment of the bonding force to be applied by the bonding force generating means. In this design, a bond force adjustment adapted to the current direction of action of the bonding tool and the bond force is realized indirectly, so to speak, by means of the—in itself known—detection of the deformation of the bond wire. Details of this procedure are, among other things, the subject of previous publications by the applicant and the expert and need no further explanation here.

In a further alternative design (which can also be combined with the above-mentioned designs), the bonding device comprises a bonding force sensor for recording the effective bonding force acting on the bonding agent in a bonding step for monitoring and/or controlling the bonding process. Instead of the direction of action influencing the effective bond force or the deformation resulting from the effective bond force, in this version the bond force is directly recorded numerically and, if necessary, readjusted in the bond force setting device. This procedure for controlling a bonding process is also known to the expert and is therefore not described further here.

In addition to designs of the bonding device with which an application-dependent precise adjustment of the bonding force can be achieved in accordance with the requirements of the respective application, from the inventors' point of view, designs in which further parameters of the bonding process or those related to the bonding process can be recorded and evaluated are also advantageous.

In particular, this includes a design in which a bonding tool stop is provided in the base body of the bonding device to define a defined initial position of the bonding tool after the positioning of the bonding device with respect to the contact surface of a carrier and before the bonding step. For details please refer to the explanation of design examples below.

Furthermore, a design is considered which has a bond step path sensor for detecting the path covered by the bond tool in the bond step with respect to the bond tool stop in order to obtain a path signal for monitoring and/or controlling the bond process. Such a path sensor in the holder (suspension) of the bonding unit can track the penetration of the bonding tool into the workpiece (for example the bonding wire) and thus enable concrete statements to be made about the time sequence of the bonding step, which is of value for quality assurance or optimisation of the bonding steps, which are in particular position- or orientation-dependent.

In a further configuration, the bonding device comprises a contact pressure sensor for detecting a contact pressure force of the bonding device or bonding tool against the carrier before the start of the application of the bonding force in order to obtain a contact pressure signal which can also be used to monitor and/or control the bonding process.

In the aforementioned designs, it may be provided in particular that the bonding device the bonding force sensor and/or bonding step displacement sensor and/or contact pressure force sensor is connected to a respective input of the bonding force setting device for providing an input signal for setting or adjusting the bonding force to be applied by the bonding force generating means. Apart from the fact that signals from the corresponding sensors enable an evaluation independent of the direct control of the bonding device (e.g. for the design of future bonding processes with similar conditions), the respective sensor signal can thus be fed directly into the process control and be made effective in real time for the control of the next bonding step or steps.

In further configurations of the bonding device or an arrangement comprising such a bonding device and a handling device (e.g. an industrial robot), means are provided for image acquisition and processing of at least the bonding site and its surroundings and for obtaining corresponding information.

In particular, the bonding device itself may be provided with a camera and downstream image processing means for recording an image of a bond site and of its surroundings for evaluating the recorded image with respect to a comparison image stored in an image storage unit, as well as a bonding tool adjustment means for fine adjustment of the position of the bonding tool and/or its direction of action as a result of the image processing. On the other hand, the mentioned means for image acquisition and processing can also be provided separately from the bonding device—for example on a robot arm or in a control unit of a robot—and the bonding tool adjustment device can also be implemented there, if necessary.

In a still further configuration, it is provided that the camera and the downstream image processing device are designed to record a larger spatial area beyond a bond site and its surroundings and to evaluate the recorded image with respect to a comparison image of that larger spatial area stored in an image storage unit, and that the arrangement comprises an adjusting device for adjusting the position of a robot arm holding the bonding device and/or the alignment of the bonding device by means of the robot as a result of the comparison image processing.

The advantages and usefulness of the invention are further explained in the following description of an example of an embodiment and of aspects of embodiment using the single FIGURE.

This FIGURE shows a sketch of the principle of the internal structure of an exemplary bonding device 1 in operation, i.e. when a wire bond connection is made to a substrate 2A by means of a bonding wire 2B through a bonding tool (wedge) 3. The bonding tool 3 is mounted in a movable bonding head 4 in a familiar manner. The bonding head 4, flexibly suspended in joint parts 4a, 4b, accommodates the actual bonding unit 5, which comprises the ultrasonic transducer 6 acting on the bonding tool 3 and the bonding tool 3.

The bonding unit 5 is pressed onto the substrate 2A by a resulting total force, into which first the intrinsic mass of the bonding unit 5 or, in the case of the non-vertical direction of action with respect to a substrate assumed in the context of the invention, its direction-dependent gravity component is incorporated. Furthermore, a tension spring 7 acts, which is arranged inside the bonding head 4 and applies a fixed spring preload to the bonding unit. Finally—only during the bonding step—a so-called voice coil 8 acts on the bonding unit 5. The resultant of the above-mentioned forces leads first to the setting of a defined relative position of the bonding unit 5 in relation to the bonding head 4.

A downward movement of the bond head along its direction of action—in the FIGURE of the z-axis—finally leads to an impact on a bond site on the substrate 2A, and this impact is registered by a touchdown and deformation sensor 9.

From this “powerless” contact state, the bonding head 4 is then moved further by a defined distance until the bonding unit 5 is released from a stop 10 provided in the area of the pretension spring 7. This additional movement is necessary to give the bonding tool 3 the necessary freedom of movement to exert a force effect on the bonding wire 2B and deform it (and, in conjunction with the ultrasonic energy from the transducer 6, to form a material bond with the substrate 2A at the bonding point).

In the version shown, an additional stop 11 is fixed to the bond head 4, which presses on the substrate (component) with a much greater force than the bond force acting in the bonding step. This stop 11 is used to stabilize the position of the bonding unit and the bonding tool relative to the substrate (component). It makes it possible to detect the deformation of the bonding wire 2B in the bonding step by a deformation sensor 9 and to track it over time without the measurement result being distorted by a possible evasive movement of the substrate 2A during the application of the bonding force in the bonding step. In addition, a force sensor (not shown) can be assigned to the stop 11, which detects the stop on the substrate 2A or can signal a possible release of the substrate from the stop.

The illustrated version of wire bonder 1 works as follows:

In a first step, the entire bonding head 4 is brought up to the substrate 2A until it hits the substrate (which in the illustration shown would mean lowering, but in the case of “overhead bonding” it would mean lifting). The impact is registered by the touchdown sensor 9, and the force acting on the substrate, which is derived from the or similar The force acting on the substrate, which is composed of the components mentioned above, is determined using signals from the deformation sensor 9 or a position sensor 12 and, if necessary, readjusted using the voice coil 8.

Then the bonding unit is moved on against the spring force of the spring 7 to gain the necessary movement space for the bonding tool 3 to deform the bonding wire 2B. Finally, the bonding step takes place, in which a higher pressure force is generated by the voice coil 8, depending on the direction of action of the bonding unit and the bonding tool detected by the position sensor.

The implementation of the invention is not limited to this example and the aspects highlighted above, but possible also in manifold modifications and combinations within the scope of the pending claims.

1. Bonding device for producing bond connections, in particular wire bond connections, tape bond connections and ball bond connections, on carriers fixed outside the bonding device and having contact surfaces for the bond connections, in different spatial directions with respect to the respective carrier, the bonding device comprising
a basic body,
a bonding tool movable relative to the base body for applying a bonding force to a bonding material placed on the contact surface of the carrier to produce a material bond between the bonding material and the contact surface as a bonding connection and
bonding force generating means for generating a bonding force directed to the contact surface when the bonding device is placed on the carrier,
wherein said bonding force generating means comprises a bonding force setting means for realizing a predetermined effective bonding force independent of the spatial direction of action thereof.

2. Bonding device according to claim 1, designed as a hand-held or robot-guided device with a handle or coupling piece for connection to a robot arm on the base body.

3. Bonding device according to claim 1, designed as wire bonding device, with
bonding wire feeding means for feeding a bonding wire as a bonding material onto the contact surface of the respective carrier, and
an ultrasonic transducer mechanically connected to the bonding tool to generate ultrasonic vibrations acting on the bonding tool.

4. Bonding device according to claim 1, designed as ball bonding device, with
bonding wire feeding means for feeding a bonding wire as a bonding material onto the contact surface of the respective carrier, and
a wire melting device for melting a free end of the bonding wire to produce a bond ball.

5. Bonding device according to claim 1, designed as TAB bonding device, with
bonding foil feeding means for feeding a bonding foil as a bonding material onto the contact surface of the respective carrier, and
an ultrasonic transducer mechanically connected to the bonding tool to generate ultrasonic vibrations acting on the bonding tool.

6. A bonding apparatus according to claim 1, wherein the bonding force setting means comprises
a position sensor for determining the spatial position of the direction of action of the bonding tool and
a calculation unit connected on its input side to the position sensor for the position-dependent calculation of the bonding force to be applied by the bonding force generating means.

7. A bonding apparatus according to claim 1, wherein the bonding force setting means comprises
a bonding wire deformation sensor for determining a deformation of the bonding wire under the effect of the set bonding force, and
has a bonding force adjustment unit connected on the input side to the bonding wire deformation sensor for deformation-dependent adjustment of the bonding force to be applied by the bonding force generating means.

8. Bonding device according to claim 1, which has a bonding force sensor for detecting the effective bonding force acting on the bonding material in a bonding step for monitoring and/or controlling the bonding process.

9. Bonding device according to claim 1, wherein a bonding tool stop is provided in the base body of the bonding device for presetting a defined initial position of the bonding tool after the positioning of the bonding device with respect to the contact surface of a carrier and before the bonding step.

10. Bonding apparatus according to claim 9, which has a bonding step displacement sensor for detecting a path covered in the bonding step by the bonding tool with respect to the bonding tool stop to obtain a path signal for monitoring and/or controlling the bonding process.

11. Bonding device according to claim 9, which has a contact pressure force sensor for detecting a contact pressure force of the bonding device or bonding tool against the carrier before the start of the application of the bonding force in order to obtain a contact pressure force signal for at least one of monitoring and controlling the bonding process.

12. Bonding device according to claim 8, wherein the bonding force sensor is connected to a respective input of the bonding force setting device for providing an input signal for setting or adjusting the bonding force to be applied by the bonding force generating means.

13. Bonding device according to claim 10, wherein the bonding step displacement sensor is connected to a respective input of the bonding force setting device for providing an input signal for setting or adjusting the bonding force to be applied by the bonding force generating means.

14. Bonding device according to claim 11, wherein the contact pressure force sensor is connected to a respective input of the bonding force setting device for providing an input signal for setting or adjusting the bonding force to be applied by the bonding force generating means.

15. Bonding device according to claim 1, having a camera and downstream image processing device for recording an image of a bond site and of its surroundings for evaluating the recorded image with respect to a comparison image stored in an image storage unit, and a bonding tool adjusting device for fine adjustment of the position of the bonding tool and/or its direction of action as a result of the image processing.

16. Bonding arrangement with a bonding device according to claim 1 and, separately from the bonding device, with a camera and downstream image processing device for recording an image of a bond site and of its surroundings for evaluating the recorded image with respect to a comparison image stored in an image storage unit, and a bonding tool adjusting device for fine adjustment of the position of the entire bonding device or of the bonding tool and/or of its direction of action as a result of the image processing.

17. Bonding arrangement according to claim 16, wherein the camera and the downstream image processing device are designed to record a larger spatial region beyond the bond site and its surroundings and to evaluate the recorded image with respect to a comparison image of that larger spatial region stored in an image storage unit, and the arrangement comprises an adjusting device for adjusting the position of a robot arm holding the bonding device and/or the orientation of the bonding device by means of the robot as a result of the comparison image processing.
